(19) United States
(12) Patent Application Publication
(10) Pub. No.: US 2015/0027968 A1
(43) Pub. Date: Jan. 29, 2015

(54) STRUCTURE FOR FIXING RACK MOUNT KIT

(71) Applicant: FUJITSU LIMITED, Kawasaki-shi (JP)

(72) Inventor: Hajime MURAKAMI, Kawaskai (JP)

(21) Appl. No.: 14/314,206

(22) Filed: Jun. 25, 2014

(30) Foreign Application Priority Data
Jul. 24, 2013 (JP) 2013-153705

(51) Int. Cl. H05K 7/14

(52) U.S. Cl. CPC H05K 7/1489
USPC 211/26

(57) ABSTRACT

A structure installed at an end of a rack mount kit to fix the rack mount kit to a column of a rack, the structure includes: one pair of claws; a first biasing unit configured to bias the one pair of claws in a direction in which the one pair of claws is opened; and a second biasing unit configured to sense that the one pair of claws is moved in an insertion direction and bias the claws in a direction in which the one pair of claws is closed.

### CROSS-REFERENCE TO RELATED APPLICATION

This application is based upon and claims the benefit of priority of the prior Japanese Patent Application No. 2013-153705 filed on Jul. 24, 2013, the entire contents of which are incorporated herein by reference.

### FIELD

The embodiments discussed herein are related to a structure for fixing a rack mount kit for mounting a rack mount server (hereinafter, referred to as a “server”) on a rack (a shelf that accommodates a server).

### BACKGROUND

FIG. 1 is a view for explaining a method of mounting a server on a rack. As illustrated in FIG. 1, when a server 80, for example, having a weight of about 10 Kg to 60 Kg is installed on a rack 10 which is installed in, for example, a data center, a rack mount kit 30 is first attached to the inside of the rack 10.

When the server 80 is installed on the rack that complies with the standard defined by the Electronic Industry Association (EIA) in the United States, the rack mount kit 30 is first fixed using holes 22 in the mount angles 20 that are disposed at four corners of the rack. The rack mount kit 30 is fixed using a plurality of holes 22 in the mount angles 20 according to the size of the server. For example, when the server having a 1U (unit) size is installed, the rack mount kit 30 is fixed using three holes 22 in the mount angles 20. Thereafter, the server 80 is mounted on the rack mount kit 30, and fixed to the rack 10 by, for example, screws.

In attaching the rack mount kit to a rack, the rack mount kit is fixed by screws. However, there is a rack mount kit which is configured to be fixed in a toolless manner in order to improve workability. The rack mount kit has a fixing structure that is attachable/detachable to/from the rack by fixing a block, which is attachable to the rack, to a leaf spring, and deforming the leaf spring. When the rack mount kit is attached to the rack, the rack mount kit is fixed by deforming the leaf spring using a column of the rack, and when the rack mount kit is removed from the rack, the rack mount kit is removed by deforming the leaf spring by hand, and as a result, a tool such as a screw driver is not needed.

When the rack mount kit 30 once attached to the rack 10 is removed from the mount angles 20 at the front side of the rack 10, the rack mount kit 30 may be removed by deforming the leaf spring by hand in front of the rack. FIG. 2 is a front view illustrating a state where a plurality of servers 80 is mounted on the rack 10. As illustrated in FIG. 2, when the plurality of servers 80 is mounted on the rack 10 and the servers 80, which become the objects, have a thickness of the smallest unit (1U) in a state where the servers 80 and closing plates 90 for cooling are mounted in the vertical direction, a gap (1U gap) is merely about 45 mm. In addition, the mount angles 20 at the front side and rear side of the rack 10 are spaced apart from each other by 700 mm or more. For this reason, it is difficult to remove the rack mount kit 30 from the mount angles 20 disposed at the rear side of the rack 10 by extending the hand from the front side of the rack.

Therefore, in order to remove the rack mount kit 30 from the mount angles 20 disposed at the rear side of the rack 10, it is needed to move the rack 10 backward to deform and remove the leaf spring.

FIG. 3 is a view illustrating a state in which a plurality of racks 10 is disposed in a server room when viewed from a ceiling. As illustrated in FIG. 3, the plurality of racks 10 is arranged side by side in the server room. A passage (cold aisle) for air for cooling the server is formed at the front side of the racks 10. A passage (hot aisle) for hot air discharged from the interior of the server is formed at the rear side of the racks 10. Since a plurality of wires such as power source wires and interface wires is led out from the rear side of the racks 10 in the hot aisle, it is difficult to perform work.

In a relatively large server room such as a data center, racks are arranged over 10 m or more although it varies depending on the scale of the server room. Thus, in some cases, it is needed to move 10 m or more to get to the rear side of the racks and also to move 10 m or more to get back. Consequently, work efficiency is not good.

The following is a reference document.

[Document 1] Japanese Patent Application Laid-Open No. 2009-206129

### SUMMARY

According to an aspect of the invention, a structure installed at an end of a rack mount kit to fix the rack mount kit to a column of a rack, the structure includes: one pair of claws; a first biasing unit configured to bias the one pair of claws in a direction in which the one pair of claws is opened; and a second biasing unit configured to sense that the one pair of claws is moved in an insertion direction and bias the claws in a direction in which the one pair of claws is closed.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view for explaining a method of mounting a server on a rack;

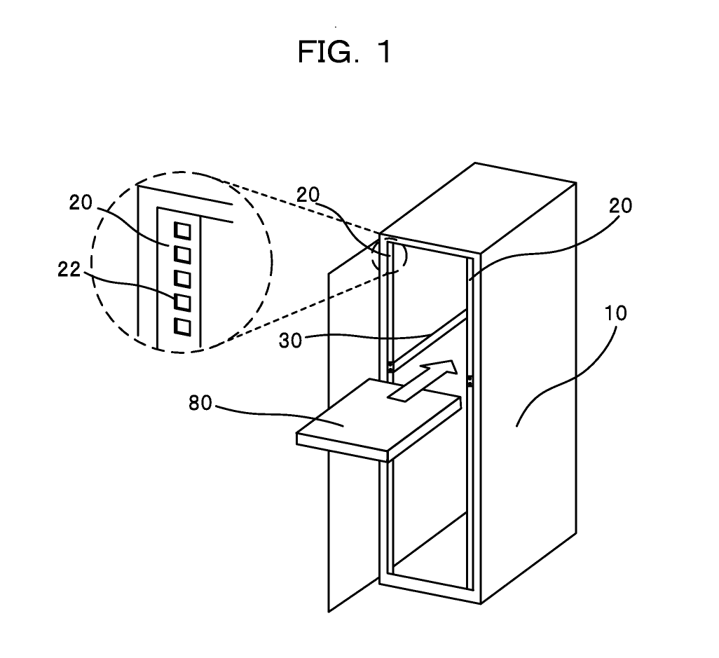

FIG. 2 is a front view illustrating a state in which a plurality of servers is mounted on the rack;

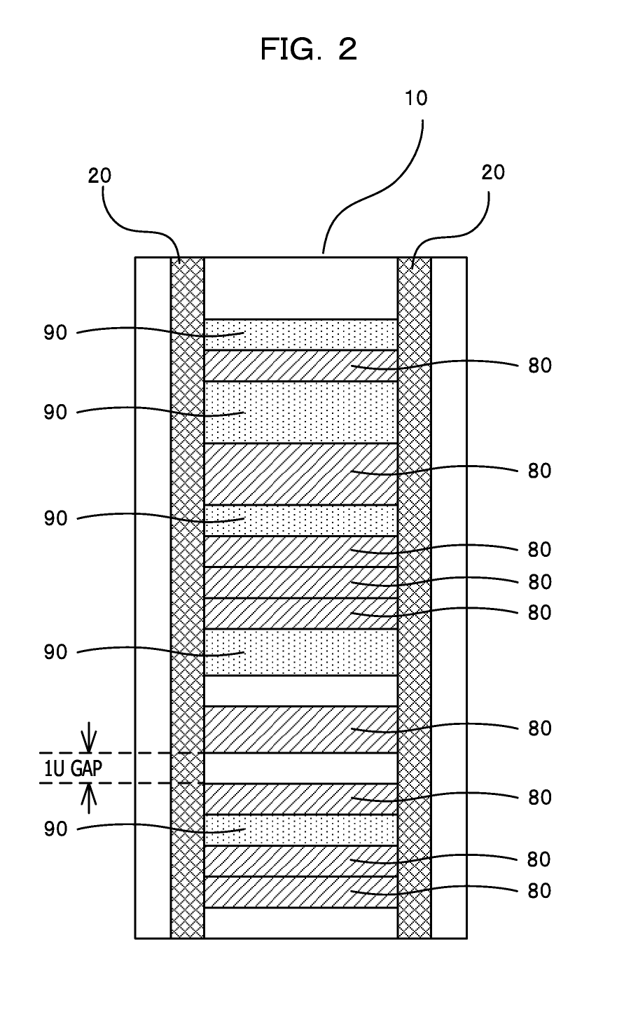

FIG. 3 is a view illustrating a state in which a plurality of racks is disposed in a server room;

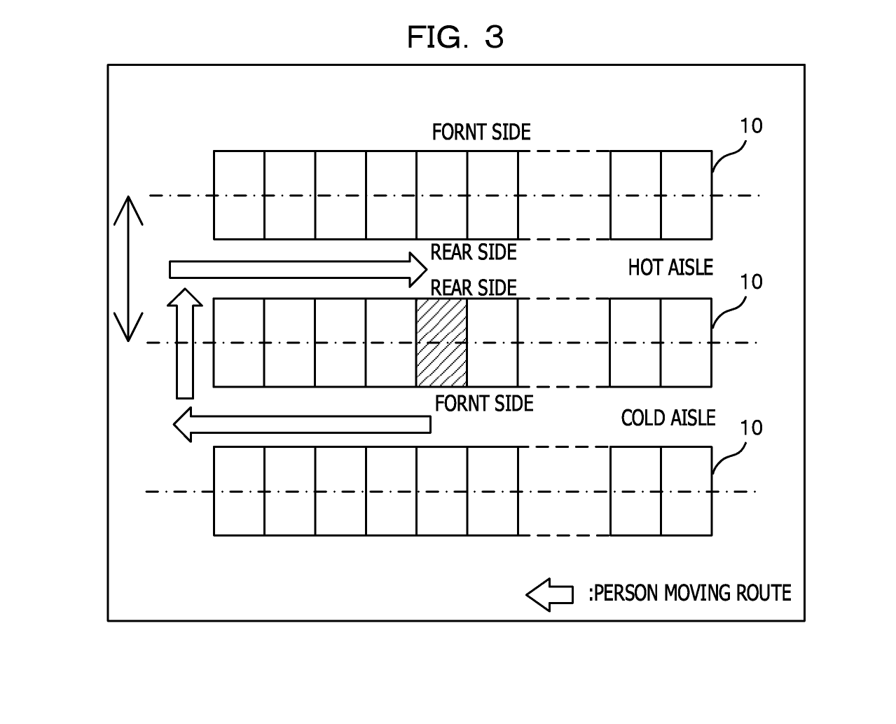

FIGS. 4A and 4B are views illustrating an exemplary embodiment of a structure for fixing a rack mount kit;

FIGS. 5A and 5B are views illustrating external appearances of a claw and a button of the rack mount kit of the exemplary embodiment, respectively;

FIGS. 6A and 6B are views for describing a structure of a rear fixing unit of the exemplary embodiment;

FIGS. 7A and 7B are views for describing a structure of the rear fixing unit of the exemplary embodiment;

FIGS. 8A and 8B are views for describing an operation of the claw and the button of the exemplary embodiment;

FIGS. 9A and 9B are views for describing the operation transition of the rear fixing unit when the rack mount kit is fixed to a mount angle;

FIGS. 10A and 10B are views for describing the operation transition of the rear fixing unit when the rack mount kit is fixed to the mount angle;

FIGS. 11A to 11C are views for describing the operation transition of the rear fixing unit when the rack mount kit is detached from the mount angle;

FIGS. 12A to 12C are views for describing a sequence of attaching the rack mount kit to the mount angle;

FIGS. 13A to 13C are views for describing a sequence of removing the rack mount kit from the mount angle; and

FIGS. 14A and 14B are views illustrating an estimation of working times according to a method in the related art and a method of the present exemplary embodiment.

### DESCRIPTION OF EMBODIMENTS

Hereinafter, an embodiment suitable for the disclosed technology will be described in detail with reference to the drawings.

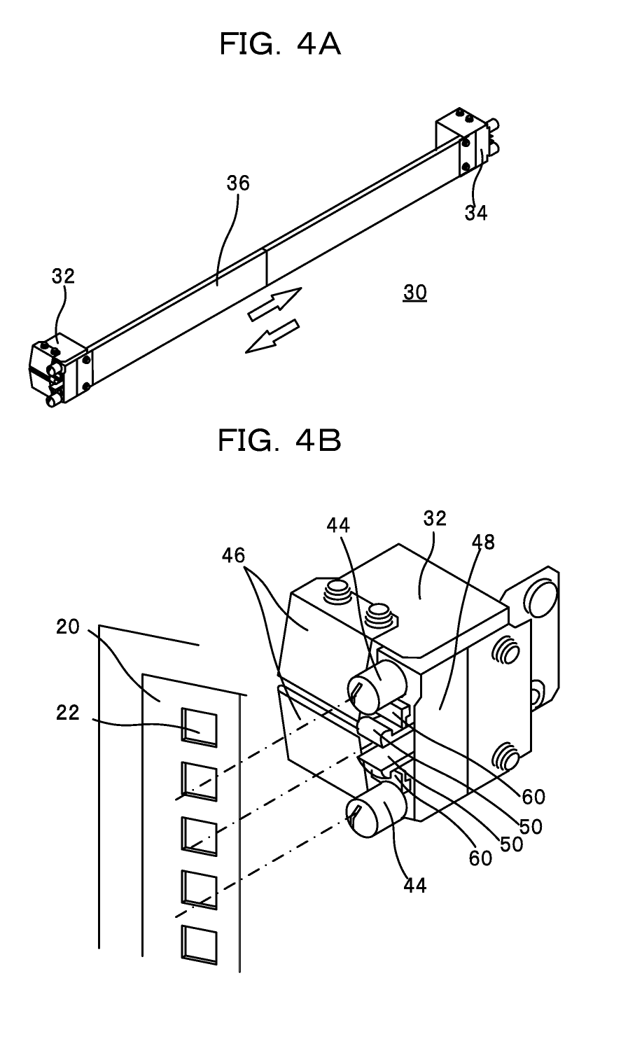

FIG. 4A is a view illustrating an exemplary embodiment of a structure for fixing a rack mount kit.

A rack mount kit 30 of the present exemplary embodiment includes a rear fixing unit 32 configured to be fixed using a hole 22 in a mount angle 20 disposed at the rear side of a rack, a front fixing unit 34 configured to be fixed using a hole 22 in a mount angle 20 disposed at the front side of the rack, and a slide unit 36 configured to interconnect the two fixing units. The slide unit 36 is extendable and a server may be mounted on the slide unit 36. The slide unit 36 is set to a length that, when the rack mount kit 30 is shortened, allows the rear fixing unit 32 to come into contact with and push the mount angle 20 at the front side of the rack.

FIG. 4B illustrates an enlarged view of the rear fixing unit 32 configured to attach the rack mount kit 30 of the present embodiment to the mount angle 20 disposed at the rear side of the rack.

A base 48 is a component configured to fix and accommodate guide pins 44, spring members 46, claws 50, and buttons 60, and includes, for example, holes and grooves where the claws 50 and the buttons 60 are fixed.

The guide pins 44 serve to position the rack mount kit 30 when the rack mount kit 30 is fixed to the mount angles 20 of the rack. The guide pins 44 have a cross-sectional shape that is smaller than that of the holes 22 of the mount angles 20 of the rack, and has a length that allows the guide pins 44 to be caught by the holes 22 so as to be positioned before tips of the claws 50 come into contact with the mount angle 20. In the present embodiment, the guide pins 44 are formed as separate components that protrude from the base 48. However, the guide pins 44 may be formed integrally with the base 48. In addition, the cross-sectional shape of each of the guide pins 44 may be a polygonal (e.g., quadrangular) shape, instead of the circular shape.

In addition, the guide pins 44 are made of a material (e.g., an iron-based material) and secure a cross-sectional area such that the guide pins 44 are not deformed even when a weight of a device is applied thereto.

The two spring members 46 have a spring force that allows the buttons 60 not to be pressed by a force which is equal to or less than the force to be applied to the buttons 60 when the rack mount kit 30 is removed from the mount angle 20. The force to be applied to the buttons 60 will be described below. In the present embodiment, a leaf spring is employed, but a coil spring may well be used as a substitute.

Two claws 50 are engaged in the hole 22 of the mount angle 20, and serve to fix the rack mount kit 30 to the mount angle 20 of the rack.

Two buttons 60 always protrude from the base 48 by button springs (e.g., coil springs) 76 in such a manner that the buttons are not moved by a force less than the force to be applied to the buttons 60 when the rack mount kit 30 is removed from the mount angles 20 of the rack.

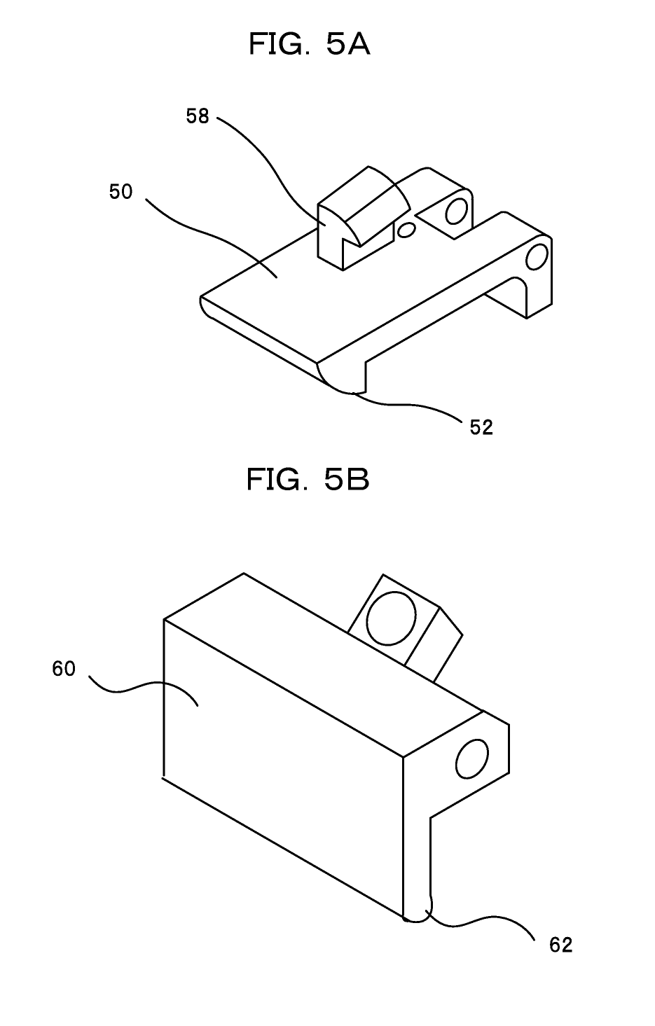

FIG. 5A is a view illustrating an external appearance of a claw 50. The two claws 50 employ the same components in terms of using components in common.

A tip 52 of the claw 50 has a hook shape that is insertably hooked by the hole 22 of the mount angle 20 of the rack. In addition, the claw 50 has a hook-shaped projection 58.

The claws 50 have a structure in which the claws 50 may be rotated about a claw fixing shafts 70 to be described below and in an axial direction of the claw fixing shafts 70. When the rack mount kit 30 is attached to the rack, the tips 52 of the claws 50 pass through the hole 22 while being rotated in a direction in which the claws 50 are closed. In this case, the hook-shaped projections 58 of the claws 50 are not hooked to each other. In addition, the claws 50 have a structure in which the claws 50 are rotated in a direction in which the claws 50 are opened after passing through the hole 22.

The claws 50 have a structure in which force is always applied in the direction in which the claws 50 are opened by claw springs 74 (e.g., torsion springs).

The hook-shaped projections 58 of the claws 50 have a structure in which, when the claws 50 are rotated inward by being pressed by the buttons 60, the hook-shaped projections 58 are hooked to each other to be maintained in the closed state. The claws 50 have a structure in which the claws 50 may also be moved in the axial direction of the claw fixing shafts 70 while being rotated about the claw fixing shafts 70 so that the hook-shaped projections 58 are hooked to each other.

The claws 50 are maintained in the closed state by claw springs 72 (e.g., coil springs) configured to apply force in the axial direction, and an inner wall of the base 48. The hook-shaped projections 58 are inclined so that the tips 52 of the two claws 50 do not come into contact with each other when the two claws 50 are rotated in the direction in which the claws 50 are closed.

FIG. 5B is a view illustrating an external appearance of a button 60. Two buttons employ the same components in terms of using the components in common.

The buttons 60 have a structure in which the buttons 60 always protrude from the base by the button springs 76 (e.g., coil springs) such that the buttons do not move only when it is necessary. The button springs 76 will be described below. The buttons 60 include tip projections 62 configured to be moved inward when pressed, and rotate the claws 50 inward while being moved.

When the rack mount kit 30 is removed from the mount angles 20 of the rack, the two buttons 60 serve to move the two claws 50 in the direction in which the claws 50 are closed, and allow the hook-shaped projections 58, which are disposed at the sides where the two claws 50 face each other, to be engaged with each other, thereby maintaining the two claws 50 in the closed state.

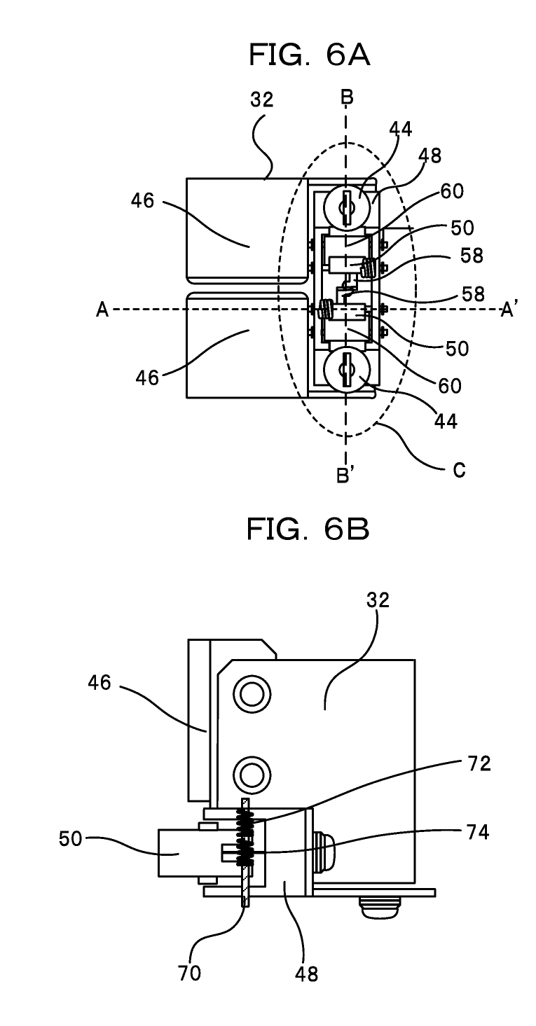

Subsequently, the structure of the rear fixing unit 32 will be described. FIG. 6A is a front view of the rear fixing unit 32. FIG. 6B is a cross-sectional view taken along dashed line A-A′ of FIG. 6A.

Referring to FIG. 6A, the two claws 50 are accommodated in the base 48, and disposed in a direction in which the hook-shaped projections 58 of the two claws 50 face each other.

Referring to FIG. 6B, the claws 50 are attached to the base 48 through the claw fixing shafts 70 that penetrate the claws 50 and the base 48. Therefore, the claws 50 may be moved in a direction in which the claws 50 are rotated about the claw fixing shafts 70. The claw coil springs 72 are attached at one sides of the claw fixing shafts 70 between the claws 50 and the base 48 to serve to bias the claws 50 against an inner wall of the other side of the base 48.

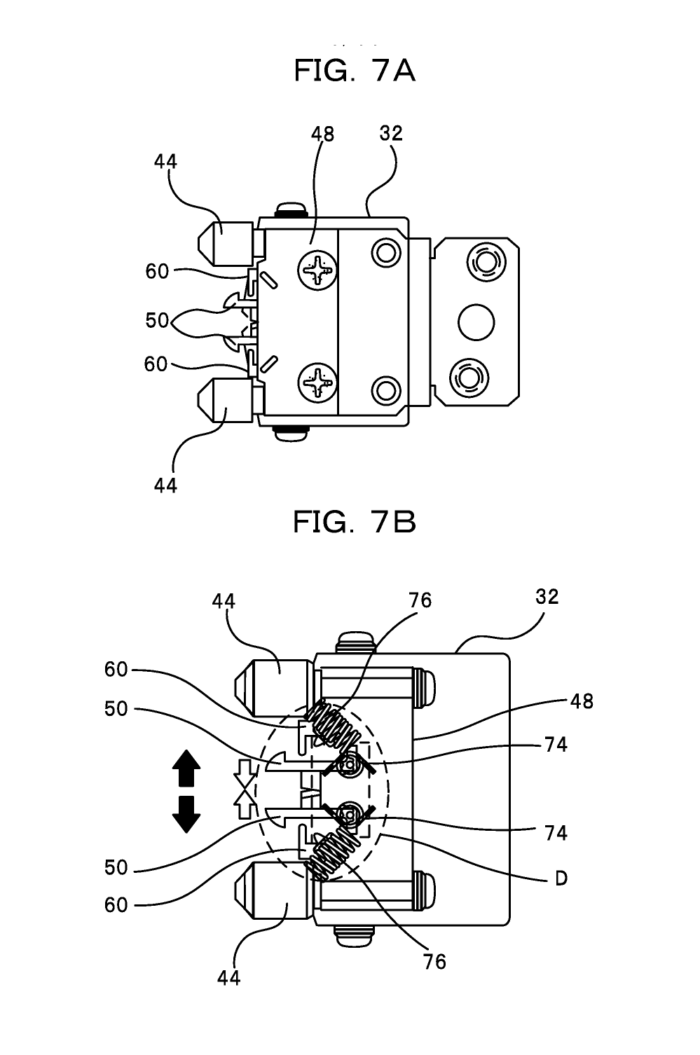

FIG. 7A is a side view of the rear fixing unit 32. FIG. 7B is a cross-sectional view taken along dashed line B-B′ of FIG. 6A. Referring to FIG. 7A, the tips of the claws 50 and the tips of the buttons 60 protrude from the base 48 between the two guide pins 44.

Referring to FIG. 7B, the claw springs 74 (e.g., torsion springs) are attached at the center of the claw fixing shafts 70 so that the claws 50 are always biased in the direction in which the claws 50 are opened. In addition, the buttons 60 are always biased in a direction in which the buttons 60 protrude from the base by the button springs 76 (e.g., coil springs).

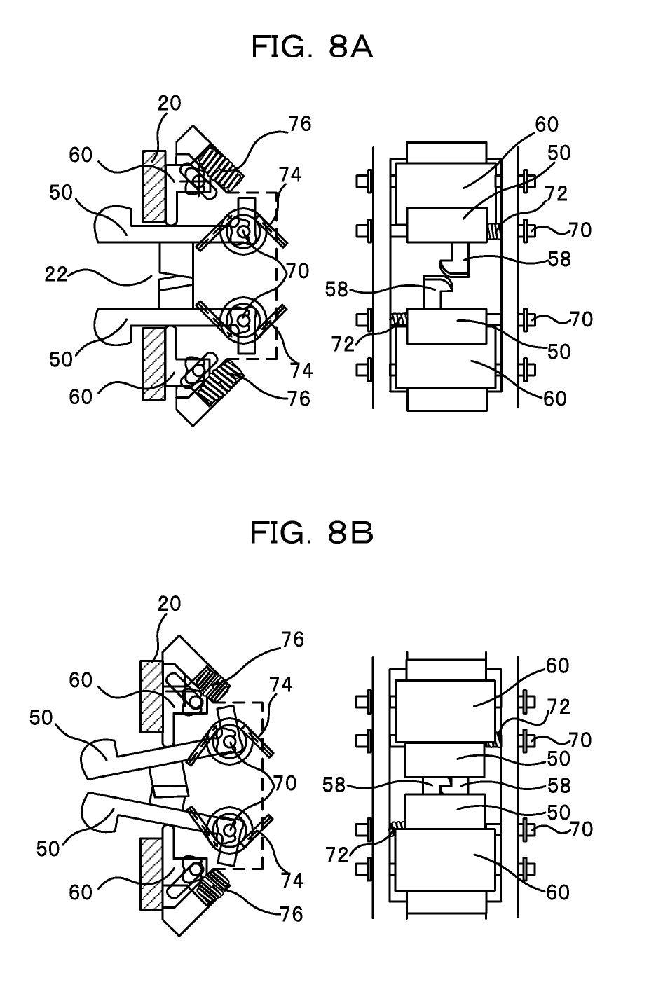

Subsequently, the operations of the claws 50 and the buttons 60 will be described with reference to FIG. 8.

In the drawing, the left view is an enlarged view of ellipse portion D of FIG. 7B, and the right view is an enlarged view of ellipse portion C of FIG. 6A.

FIG. 8A illustrates a positional relationship between the claws 50 and the buttons 60 in a state in which the rear fixing unit 32 is fixed to the mount angle 20 of the rack. Referring to the left view of FIG. 8A, since the claws 50 are engaged within the hole 22 of the mount angle 20 of the rack, the claws 50 are in an opened state. The state is identical to the initial state before the rear fixing unit 32 is attached to the mount angle 20.

Referring to the right view of FIG. 8A, in this state, the hook-shaped projections 58, which are disposed at the sides where the two claws 50 face each other, are spaced apart from each other.

FIG. 8B illustrates a positional relationship between the claws 50 and the buttons 60 in a state in which the rear fixing unit 32 is removed from the mount angle 20 of the rack. When the buttons 60 are tightly pressed against the mount angle 20 of the rack, the buttons 60 slides in a direction inclined at 45° which is opposite to the direction of the mount angle 20. As a result, the two claws 50 are rotated about the claw fixing shafts 70 in the direction in which the claws 50 are closed by the tip projections 62 of the buttons 60.

Referring to the right view of FIG. 8B, when the two claws 50 are rotated in the direction in which the claws 50 are closed, the hook-shaped projections 58, which are disposed at the sides where the two claws 50 face each other, are engaged with each other. Since the two claws 50 are biased in a direction in which the hook-shaped projections 58 are engaged with each other by the claw coil springs 72, the state in which the hook-shaped projections 58 are engaged with each other is maintained.

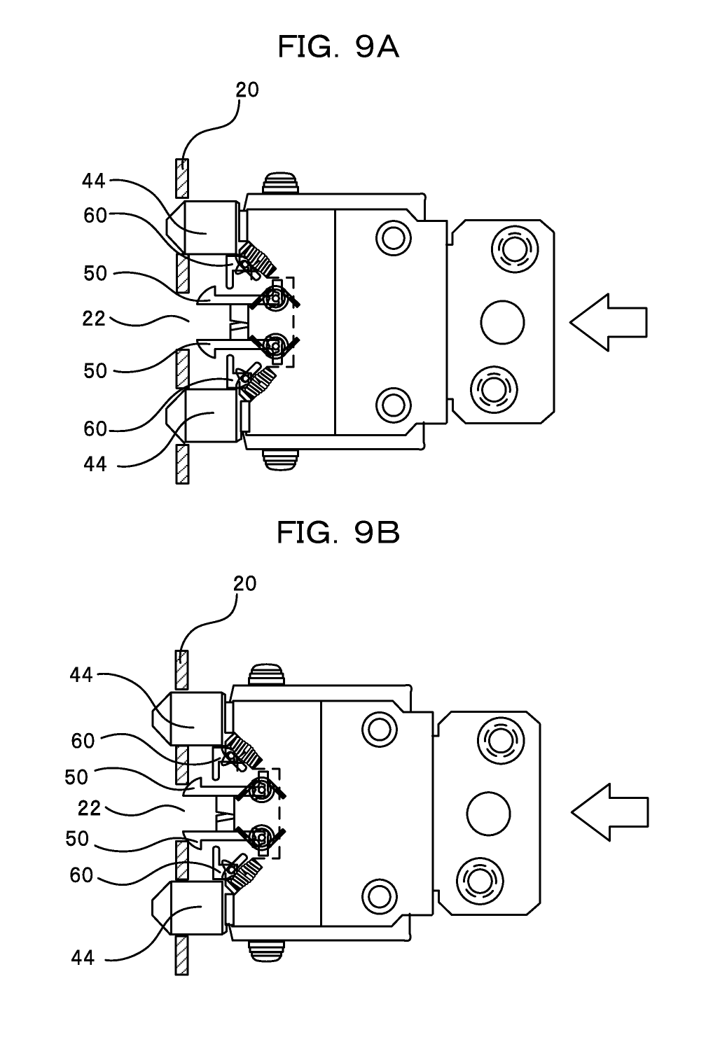

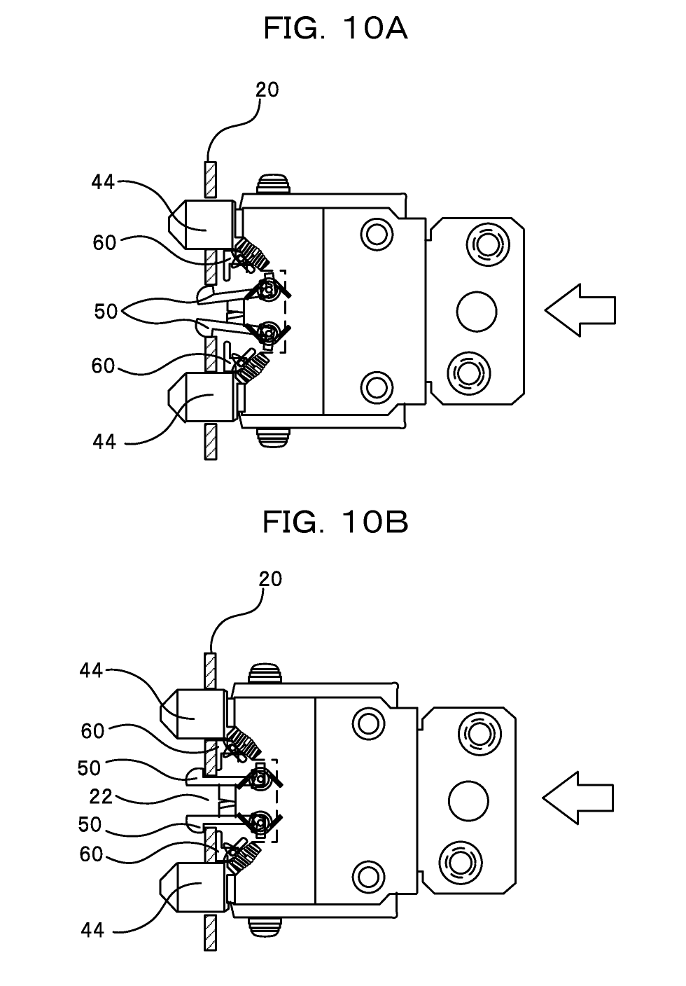

FIGS. 9A and 9B and FIGS. 10A and 10B are views for explaining the operational progress of the claws 50 and the buttons 60 of the rear fixing unit 32 when the rack mount kit 30 is fixed to the mount angle 20 of the rack.

FIG. 9A illustrates a state in which the rack mount kit 30 is being inserted at the front side of the rack, and the insertion position of the guide pins 44 at the front end of the rear fixing unit 32 is determined with respect to the hole 22 of the mount angle 20 disposed at the rear side of the rack.

FIG. 9B illustrates a state in which, when the rack mount kit 30 is further inserted into the mount angle 20, the tips of the claws 50 are deeply inserted into the hole 22 of the mount angle 20.

Referring to FIG. 10A, when the rack mount kit 30 is further inserted into the mount angle 20, the tips of the claws 50 are deeply pressed into the hole 22 of the mount angle 20, and the claws 50 are rotated about the claw fixing shafts 70 in the direction in which the claws 50 are closed.

Referring to FIG. 10B, when the rack mount kit 30 is further inserted into the mount angle 20, the tips of the claws 50 pass through the hole 22 of the mount angle 20. Since the claws 50 are always biased in the direction in which the claws 50 are opened by the claw springs 74, the claws 50 are rotated about the claw fixing shafts 70 in the direction in which the claws 50 are opened, and the tips of the claws 50 are deeply engaged within the hole 22. Accordingly, the rack mount kit 30 is fixed to the mount angle 20.

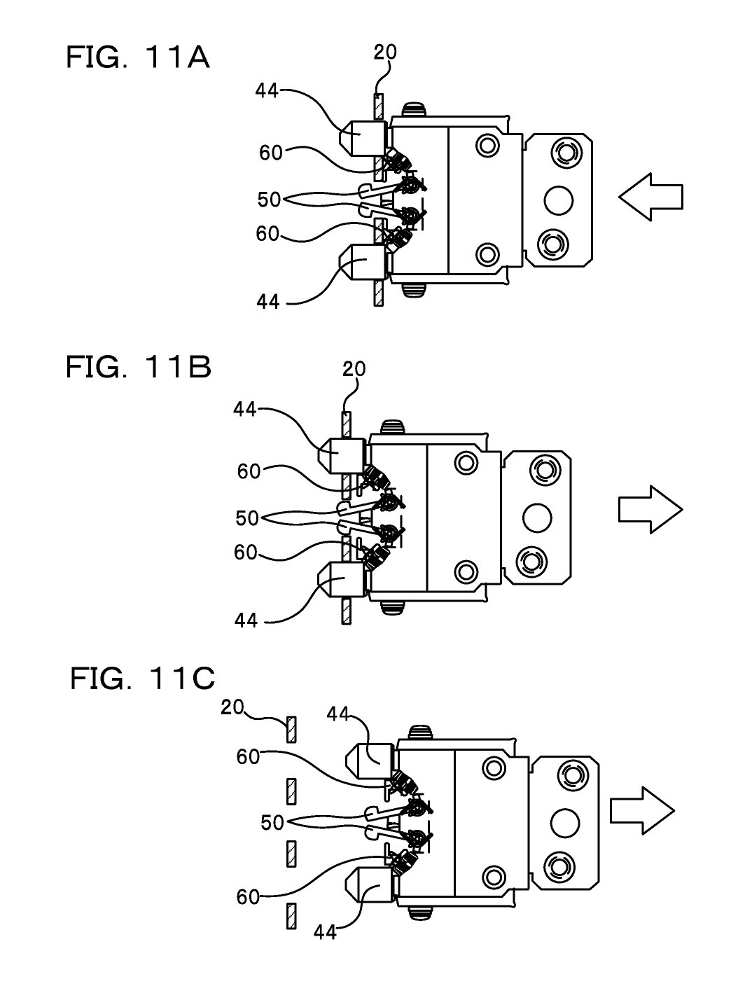

FIGS. 11A to 11C are views for describing the operational progress of the claws 50 and the buttons 60 of the rear fixing unit 32 when the rack mount kit 30 is detached from the mount angle 20 of the rack.

FIG. 11A illustrates a state in which the rack mount kit 30 is once further inserted into the mount angle 20 in a state in which the tips of the claws 50 of the rear fixing unit 32 of FIG. 10B are deeply engaged within the hole 22 of the mount angle 20. As described with reference to FIG. 8B, the buttons 60 are pressed against the wall of the mount angle 20 of the rack and slid in a direction inclined at 45°. As a result, the two claws 50 are rotated about the claw fixing shafts 70 in the direction in which the claws 50 are closed. Further, the hook-shaped projections 58, which are disposed at the sides where the two claws 50 face each other, are engaged with each other, and the two claws 50 are maintained in the closed state.

FIG. 11B illustrates a state in which the rack mount kit 30 is withdrawn in a state in which the two claws 50 of FIG. 11A are in the closed state.

FIG. 11C illustrates a state in which the rack mount kit 30 is completely withdrawn from the mount angle 20. The two claws 50 are maintained in the closed state.

When the rack mount kit 30 is attached to the rack again, the hook-shaped projections 58 of the claws 50 are moved by hand in the direction in which the hook-shaped projections 58 are moved away from each other, and the claws 50 are in the opened state.

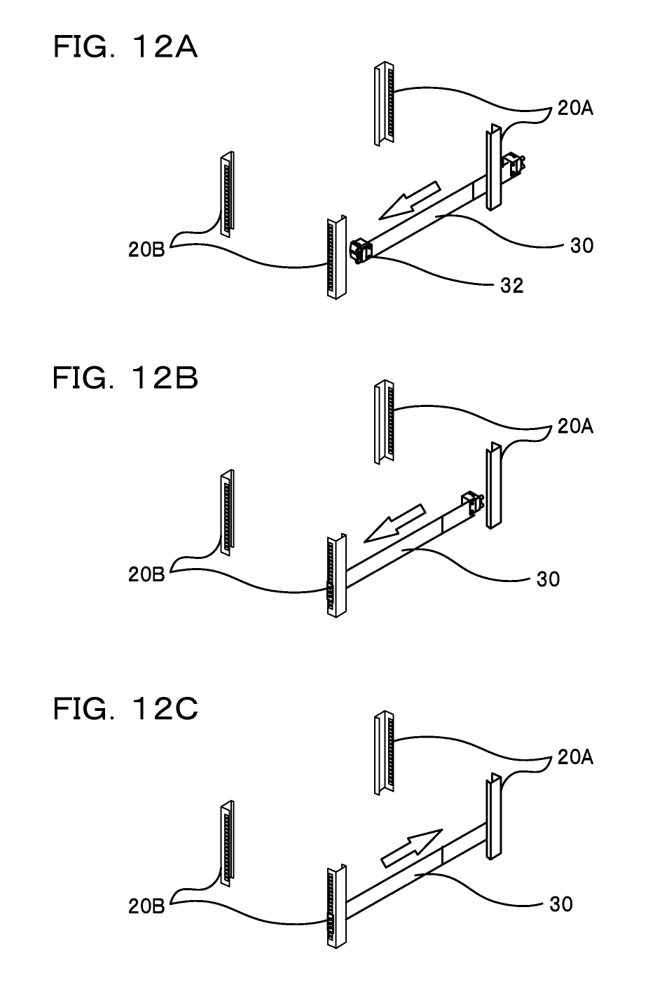

FIGS. 12A to 12C are views for describing the sequence of attaching the rack mount kit 30 to a mount angle 20A disposed at the front of the rack 10, and a mount angle 20B disposed at the rear of the rack 10. The rack mount kit 30 is fixed using three holes 22 (for 1U) in each of the mount angles 20A and 20B of the rack 10.

Referring to FIG. 12A, the rack mount kit 30 is inserted at the front side of the rack until the rear fixing unit 32 at the front end of the rack mount kit 30 comes into contact with the mount angle 20B at the rear side of the rack.

Subsequently, referring to FIG. 12B, the guide pins 44 of the rear fixing unit 32 are inserted and positioned into the holes 22 in the mount angle 20B disposed at the rear side of the rack. In addition, as the rack mount kit 30 is inserted, the two claws 50 of the rear fixing unit 32 are engaged in the corresponding hole 22 of the mount angle 20B, and the rear fixing unit 32 is fixed to the mount angle 20B disposed at the rear side of the rack.

Subsequently, referring to FIG. 12C, the rack mount kit 30 is moved back to the front side of the rack from the slide unit 36, and the front fixing unit 34 is attached to the mount angle 20A disposed at the front side of the rack.

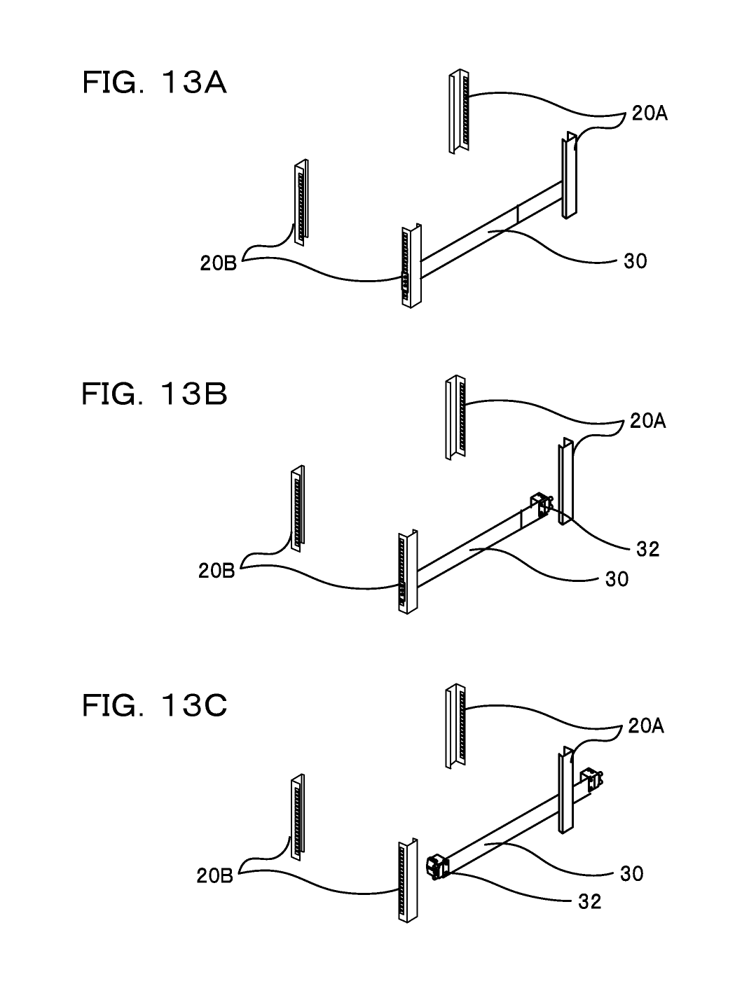

FIGS. 13A to 13C are views for describing a sequence of removing the rack mount kit 30 from the mount angle 20A disposed at the front side of the rack and the mount angle 20B disposed at the rear side of the rack.

Referring to FIG. 13A, the front fixing unit 34 disposed at the front side of the rack is first unlocked, and the front fixing unit 34 is removed from the mount angle 20A disposed at the front side of the rack.

Subsequently, referring to FIG. 13B, when the rack mount kit 30 is pressed from the front side of the rack to the rear side of the rack, the two claws 50 of the rear fixing unit 32 are moved in the direction in which the claws 50 are closed and, thus, the engagement of the claws 50 with the hole 22 of the mount angle 20 is released. A detailed operation thereof will be described below with reference to other drawings.

Subsequently, referring to FIG. 13C, since the engagement between the two claws 50 of the rear fixing unit 32 and the hole 22 of the mount angle 20 is released, the rack mount kit 30 may be removed when the rack mount kit 30 is withdrawn to the front of the rack in this state. The rear fixing unit 32 of the rack mount kit 30 may be attached to the opposite side of the rack 10. In this case, the direction in which the rear fixing unit 32 is pressed when the rack mount kit 30 is attached or detached is reversed.

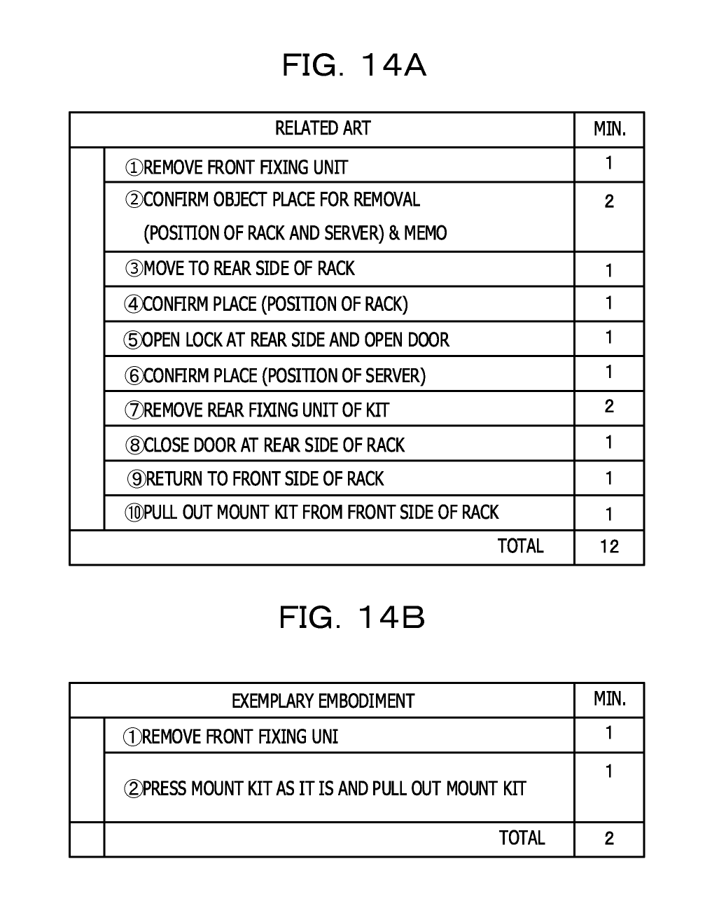

FIGS. 14A and 14B illustrate an estimation of working time when using a method in the related art and working time when using the rack mount kit of the present embodiment, for removing (two) rack mount kits for one server. While it takes about 12 minutes when using the method in the related art, it takes merely two minutes when using the rack mount kit of the present exemplary embodiment. In a case of using the rack mount kit of the present exemplary embodiment, the working time may be shortened by about 10 minutes, thereby greatly improving working efficiency.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A structure installed at an end of a rack mount kit to fix the rack mount kit to a column of a rack, the structure comprising:
one pair of claws;
a first biasing unit configured to bias the one pair of claws in a direction in which the one pair of claws is opened; and
a second biasing unit configured to sense that the one pair of claws is moved in an insertion direction and bias the claws in a direction in which the one pair of claws is closed.

2. The structure according to claim 1, wherein
biasing force of the second biasing unit is stronger than biasing force of the first biasing unit.

3. The structure according to claim 1, wherein
the one pair of claws includes a maintaining unit configured to maintain an interval between the one pair of claws with a predetermined interval.

4. The structure according to claim 3, wherein
the maintaining unit is hook-shaped projections provided on the one pair of claws, and, when the one pair of claws is biased in the direction in which the claws are closed by the second biasing unit, the hook-shaped projections are engaged with each other to maintain the interval between the one pair of claws at the predetermined interval.

5. The structure according to claim 1, wherein
the one pair of claws are rotated about shafts, respectively, and the first biasing unit is springs that are attached to the shafts and bias the one pair of claws in the direction in which the one pair of claws is opened.

6. The structure according to claim 1, wherein
the one pair of claws include hook-shaped tip portions at a front ends thereof in the insertion direction, respectively, and an outer diameter of the hook-shaped tip portions of the one pair of claws is greater than a diameter of a hole provided in the column of the rack.

7. The structure according to claim 6, wherein
when the one pair of claws is maintained at a predetermined interval, the outer diameter of the hook-shaped tip portions of the one pair of claws becomes smaller than the diameter of the hole provided in the column of the rack.

8. The structure according to claim 1, wherein
when the claws are moved farther than the second biasing unit in the insertion direction, the second biasing unit is inclined and slid in a direction opposite to the insertion direction and biases the claws in the direction in which the one pair of claws is closed.

9. The structure according to claim 8, wherein
a second spring is installed in the second biasing unit, and the second spring biases the second biasing unit which is inclined and slid toward an original position.
